(19) United States
(12) Patent Application Publication
(10) Pub. No.: US 2022/0351951 A1
(43) Pub. Date: Nov. 3, 2022

(54) SUBSTRATE SUPPORT APPARATUS, METHODS, AND SYSTEMS HAVING ELEVATED SURFACES FOR HEAT TRANSFER

(71) Applicant: Applied Materials, Inc., Santa Clara, CA (US)

(72) Inventors: Jian LI, Fremont, CA (US); Juan Carlos ROCHA-ALVAREZ, San Carlos, CA (US); Chidambara A. RAMALINGAM, Fremont, CA (US)

(21) Appl. No.: 17/244,752

(22) Filed: Apr. 29, 2021

(51) Int. Cl. H01J 37/32; H01L 21/67; H01L 21/683; H01L 21/687; C23C 16/50; C23C 16/458

(52) U.S. Cl. CPC H01J 37/32724; H01L 21/67103; H01L 21/6833; H01L 21/68742; H01L 21/6875; C23C 16/50; C23C 16/4583; H01J 2237/2007; H01J 2237/3321

(57) ABSTRACT

Aspects generally relate to substrate support apparatus and systems having elevated surfaces for heat transfer between the elevated surfaces and a substrate, and the methods of using the same. In one aspect, the elevated surfaces are disposed between a recessed surface and a plurality of support surfaces of a plurality of support protrusions that extend from the recessed surface. In one aspect, the elevated surfaces are disposed between a base surface and a plurality of support surfaces of a plurality of support protrusions that extend from the base surface. During a substrate processing operation, heat is transferred to the substrate through a plurality of cavities disposed between the elevated surfaces and a backside surface of the substrate.

### BACKGROUND

### Field

Aspects generally relate to substrate support apparatus and systems having elevated surfaces for heat transfer between the elevated surfaces and a substrate, and the methods of using the same. In one aspect, the elevated surfaces are disposed between a recessed surface and a plurality of support surfaces of a plurality of support protrusions that extend from the recessed surface. In one aspect, the elevated surfaces are disposed between a base surface and a plurality of support surfaces of a plurality of support protrusions that extend from the base surface.

### Description of the Related Art

During processing of substrates, temperature non-uniformity can occur within the substrates. For example, areas of the substrate that are above lift pin openings (and adjacent thereto) can be cooler than other areas of the substrate due. The cooler areas can result from less heat transfer to the substrate relative to the other areas, and heat loss through lift pins and the lift pin openings.

Attempts to address the temperature non-uniformity have failed and have resulted in other concerns, such as component breakage. Moreover, the temperature non-uniformity can involve problems such as deposition non-uniformity, reduced throughput, increased costs, and more complex downstream processing.

Therefore, there is a need for improved apparatus, methods, and systems that facilitate one or more of enhanced temperature uniformity during substrate processing, reduced likelihood of component breakage, increased throughput, reduced costs, and less complex downstream processing.

### SUMMARY

Aspects generally relate to substrate support apparatus and systems having elevated surfaces for heat transfer between the elevated surfaces and a substrate, and the methods of using the same. In one aspect, the elevated surfaces are disposed between a recessed surface and a plurality of support surfaces of a plurality of support protrusions that extend from the recessed surface. In one aspect, the elevated surfaces are disposed between a base surface and a plurality of support surfaces of a plurality of support protrusions that extend from the base surface.

In one implementation, a substrate support apparatus includes a support body. The support body includes a substrate support face. The substrate support face includes an outer support surface, a recessed surface disposed inwardly of the outer support surface, and a plurality of support protrusions extending from the recessed surface. The plurality of support protrusions have a plurality of support surfaces. The support body incudes a plurality of pin openings configured to received lift pins therein, and a plurality of elevated surfaces disposed between the recessed surface and the plurality of support surfaces. Each elevated surface of the plurality of elevated surfaces is disposed about a respective pin opening of the plurality of pin openings.

In one implementation, a substrate support apparatus includes a support body. The support body includes a substrate support face. The substrate support face includes a base surface and a plurality of support protrusions extending from the base surface. The plurality of support protrusions have a plurality of support surfaces. The support body includes a plurality of pin openings configured to received lift pins therein, and a plurality of elevated surfaces disposed between the base surface and the plurality of support surfaces. Each elevated surface of the plurality of elevated surfaces is disposed about a respective pin opening of the plurality of pin openings

In one implementation, a method of processing substrates includes positioning a substrate on one or more support surfaces of a substrate support apparatus disposed in a processing chamber. The positioning includes moving the substrate support apparatus relative to a plurality of lift pins disposed in a plurality of pin openings of the substrate support apparatus. The method includes conducting a substrate processing operation on the substrate. The substrate processing operation includes heating the substrate support apparatus, and transferring heat to the substrate through a plurality of cavities positioned between the substrate and a plurality of elevated surfaces. The plurality of elevated surfaces are disposed between the one or more support surfaces and one or more recessed surfaces of the substrate support apparatus. Each elevated surface of the plurality of elevated surfaces is disposed about a respective pin opening of the plurality of pin openings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross-sectional view of a processing chamber, according to one implementation.

FIG. 2A is a top schematic plan view of a substrate support apparatus, according to one implementation.

FIG. 2B is a schematic cross-sectional view of the substrate support apparatus shown in FIG. 2A, according to one implementation.

FIGS. 3A-3D are various sectional views showing a method of making the substrate support apparatus shown in FIGS. 2A and 2B, according to one implementation.

FIG. 4A is a top schematic plan view of a substrate support apparatus, according to one implementation.

FIG. 4B is a schematic cross-sectional view of the substrate support apparatus shown in FIG. 4A, according to one implementation.

FIG. 5 is a schematic block diagram view of a method of processing substrates, according to one implementation.

FIG. 6 is a top schematic plan view of a substrate support apparatus, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects generally relate to substrate support apparatus and systems having elevated surfaces for heat transfer between the elevated surfaces and a substrate, and the methods of using the same. In one aspect, the elevated surfaces are disposed between a recessed surface and a plurality of support surfaces of a plurality of support protrusions that extend from the recessed surface. In one aspect, the elevated surfaces are disposed between a base surface and a plurality of support surfaces of a plurality of support protrusions that extend from the base surface.

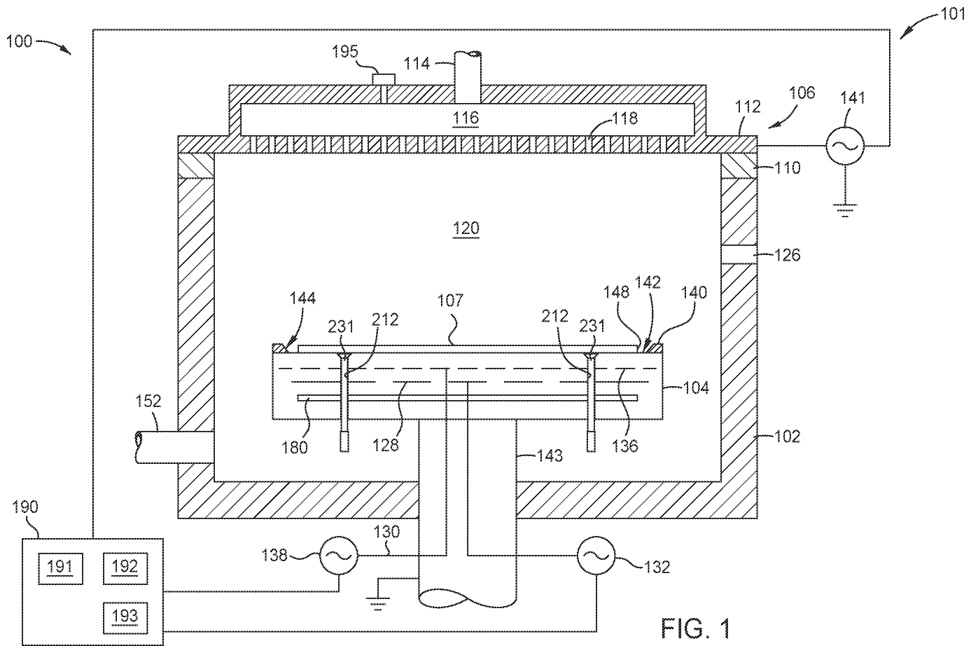

FIG. 1 is a schematic cross-sectional view of a processing chamber 100, according to one implementation. The processing chamber 100 may be a chemical vapor deposition (CVD) chamber, a plasma enhanced chemical vapor deposition (PECVD) chamber or other processing chamber, such as a processing chamber where substrates are heated. An exemplary processing chamber which may benefit from the embodiments described herein is the PRODUCER® series of PECVD enabled chambers, available from Applied Materials, Inc., Santa Clara, Calif. It is contemplated that other process chambers from other manufacturers may also benefit from the embodiments described herein. Although the processing chamber 100 is shown as a deposition chamber, the present disclosure contemplates that aspects of the present disclosure can be used in other processing chambers, such as an etch chamber, an oxidation chamber, an anneal chamber, and/or an ion implantation chamber.

The processing chamber 100 includes a chamber body 102, a pedestal 104 disposed within the chamber body 102, and a lid assembly 106 coupled to the chamber body 102 and enclosing the pedestal 104 in a processing volume 120. The lid assembly 106 includes a gas distributor 112. A substrate 107 is provided to the processing volume 120 through an opening 126 formed in the chamber body 102.

An isolator 110, which may be a dielectric material such as a ceramic or metal oxide, for example aluminum oxide and/or aluminum nitride, separates the gas distributor 112 from the chamber body 102. The gas distributor 112 includes openings 118 for admitting process gases into the processing volume 120. The process gases may be supplied to the processing chamber 100 via a conduit 114, and the process gases may enter a gas mixing region 116 prior to flowing through the openings 118. An exhaust 152 is formed in the chamber body 102 at a location below the pedestal 104. The exhaust 152 may be connected to a vacuum pump (not shown) to remove unreacted species and by-products from the processing chamber 100.

The gas distributor 112 may be coupled to an electric power source 141, such as an RF generator or a DC power source. The DC power source may supply continuous and/or pulsed DC power to the gas distributor 112. The RF generator may supply continuous and/or pulsed RF power to the gas distributor 112. The electric power source 141 is turned on during the operation to supply an electric power to the gas distributor 112 to facilitate formation of a plasma in the processing volume 120.

The pedestal 104 may be formed from a ceramic material, for example a metal oxide or nitride or oxide/nitride mixture such as aluminum, aluminum oxide, aluminum nitride, or an aluminum oxide/nitride mixture. The pedestal 104 is supported by a shaft 143. The pedestal 104 may be grounded. One or more heaters 128 are embedded in the pedestal 104. The one or more heaters 128 (one is shown) are one or more resistive heaters. The heater 128 may be a plate, a perforated plate, a mesh (such as a wire mesh), a wire screen, or any other distributed arrangement. The heater 128 is coupled to an electric power source 132 via a connection 130. The electric power source 132 may be a power supply that controls the heater 128. The electric power source 132 supplies electric power (such as an alternating current) to the heater 128 to generate heat. One or more cooling channels 180 can be formed in the pedestal 104 to cool the substrate 107. The one or more cooling channels 180 receive a cooling fluid to cool the substrate 107.

The pedestal 104 includes an electrode 136 and an electric power source 138 electrically coupled to the electrode 136. The electrode 136 may be a plate, a perforated plate, a mesh (such as a wire mesh), a wire screen, or any other distributed arrangement. The electric power source 138 is configured to supply a chucking voltage and/or RF power to the electrode 136 through the electrode 136. Using the electrode 136, the pedestal 104 is as an electrostatic chuck that chucks the substrate 107 thereto. Using the electrode 136, the electric power source 138 may be utilized to control properties of the plasma formed in the processing volume 120, or to facilitate generation of the plasma within the processing volume 120. For example, the electric power source 141 and the electric power source 138 may be tuned to two different frequencies to promote ionization of multiple species in the processing volume 120. The electric power source 141 and the electric power source 132 may be utilized to generate a capacitively-coupled plasma within the processing volume 120.

The pedestal 104 includes a substrate support face 142 for supporting the substrate 107. The pedestal 104 may also include a step 140 having a pocket 144. The step 140 may be an edge ring. The substrate 107 and the step 140 may be concentrically disposed on the substrate support face 142 of the pedestal 104. The step 140 can be integrally formed with the pedestal 104.

The pedestal 104 can be at least a part of a substrate support apparatus coupled to the shaft 143. The pedestal 104 can include a single support body, or can include a plurality of bodies, such as a top plate (a support body) having the substrate support face 142 mounted to a base plate, where the base plate is mounted to the shaft 143.

The processing chamber 100 is a part of a system 101 for processing substrates. The system 101 includes a controller 190 to control the operations of the system 101. The controller 190 includes a central processing unit (CPU) 191, a memory 192 containing instructions, and support circuits 193 for the CPU 191. The controller 190 controls the system 101 directly, or via other computers and/or controllers (not shown) coupled to the system 101. The controller 190 is of any form of a general-purpose computer processor that is used in an industrial setting for controlling various chambers and equipment, and sub-processors thereon or therein.

The memory 192, or non-transitory computer readable medium, is one or more of a readily available memory such as random access memory (RAM), read only memory (ROM), floppy disk, hard disk, flash drive, or any other form of digital storage, local or remote. The support circuits 193 are coupled to the CPU 191 for supporting the CPU 191 (a processor). The support circuits 193 include cache, power supplies, clock circuits, input/output circuitry and subsystems, and the like. Substrate processing parameters and operations are stored in the memory 192 as a software routine that is executed or invoked to turn the controller 190 into a specific purpose controller to control the operations of the system 100. The controller 190 is configured to conduct any of the methods and operations described herein. The instructions stored in the memory 192, when executed, cause one or more of operations 502-506 of method 500 to be conducted.

As an example, the instructions stored in the memory 192, when executed, cause the electric power source 132 to change a heated temperature of the one pedestal 104 using the one or more heaters 128. The system 101 can include one or more sensors 195 to measure temperatures of different zones of the substrate 107 during a substrate processing operation. As an example, the one or more sensors 195 can measure first temperatures of zones of the substrate 107 aligned vertically above the cavities 263 and the elevated surfaces 240 described below and second temperatures of zones of the substrate 107 aligned outside of the cavities 263 and the elevated surfaces 240.

The plurality of instructions executed by the controller 190 include instructions that instruct the one or more sensors 195 conduct the measurements. The one or more sensors 195 can alternatively or additionally measure properties of the substrate 101, such as film thickness and/or film uniformity. The one or more sensors 195 include one or more particle counters, metrology sensors, on-substrate spectroscopy sensors (such as X-ray fluorescence spectroscopy (XRF) sensors and/or X-ray photoelectron spectroscopy (XPS) sensors), cameras, and/or optical sensors (such as laser sensors). Sensors outside of the processing chamber 100, such as sensors coupled to a second chamber (for example a measurement chamber, a load lock chamber, a transfer chamber, a buffer chamber, an interface chamber, or a factory interface chamber), which are similar to the sensors 195 can also measure the properties of the substrate 101.

The controller 190 can determine differences between the first temperatures and the second temperatures. If the differences exceed a threshold, the controller 190 can output an alert and/or adjust a heated temperature for the pedestal 104. The alert can instruct an operator to replace the pedestal 104 (such as a support body of the pedestal 104). The instructions in the memory 192 of the controller 190 can include one or more machine learning/artificial intelligence algorithms that can be executed in addition to the operations described herein. As an example, a machine learning/artificial intelligence algorithm executed by the controller 190 can optimize and alter operational parameters (such as the heated temperature for the pedestal 104) based on the temperature measurements and/or the substrate property measurements taken by the one or more sensors 195 and/or the sensors coupled to the second chamber. The machine learning/artificial intelligence algorithm can also output the alert. The machine learning/artificial intelligence algorithm can account for stored data collected during previous iterations of substrate processing operations.

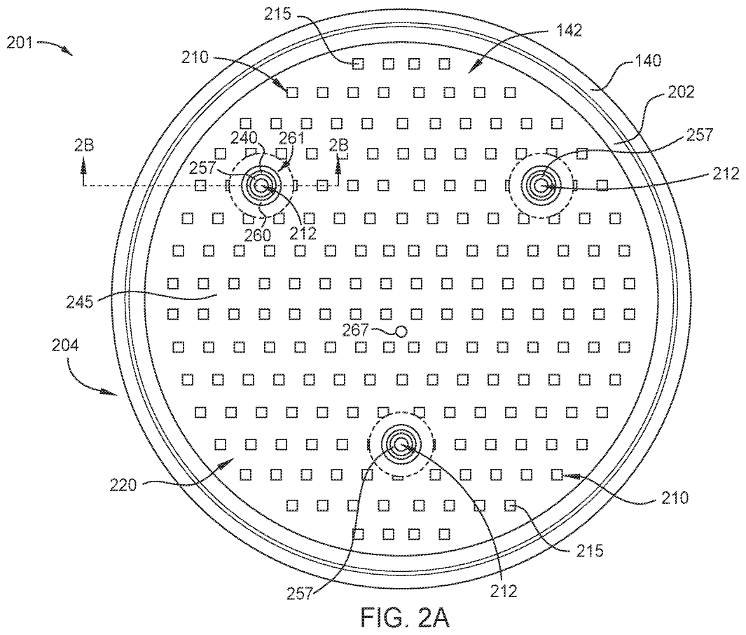

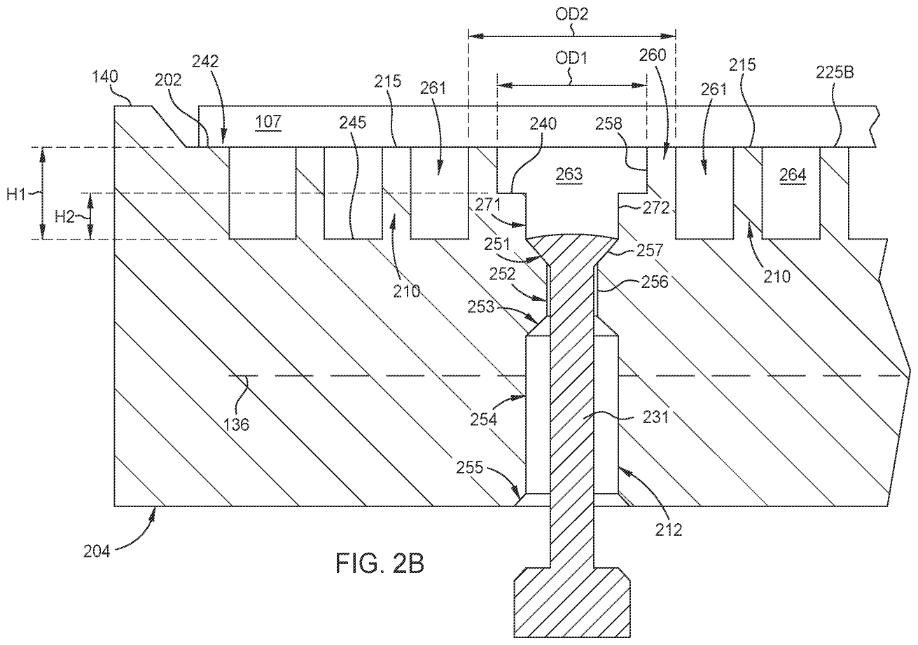

FIG. 2A is a top schematic plan view of a substrate support apparatus 201, according to one implementation. FIG. 2B is a schematic cross-sectional view of the substrate support apparatus 201 shown in FIG. 2A, according to one implementation. The substrate support apparatus 201 can be used for the pedestal 104 shown in FIG. 1.

The substrate support apparatus 201 includes a support body 204. The support body 204 shown in FIGS. 2A and 2B includes a substrate support face 242. The substrate support face 242 includes a ledge having an outer support surface 202 that is surrounded by the step 140. The substrate support face 242 includes a recessed surface 245 disposed inwardly of the outer support surface 202, and a plurality of support protrusions 210 extending from the recessed surface 245. The plurality of support protrusions 210 have a plurality of support surfaces 215 disposed on upper sides of the support protrusions 210. The support surface 215 of each of the plurality of support protrusions 210 are substantially coplanar.

Each of the support protrusions 210 is a support post (e.g., a support mesa). Each of the plurality of support protrusions 210 are shown as being rectangular in shape in plan view. The present disclosure contemplates that the support protrusions 210 may be circular, oval, hexagonal, or other shape in plan view.

A plurality of pin openings 212 (three are shown in FIG. 2A) are disposed in the support body 204. Each pin opening 212 is an aperture and is configured to receive a lift pin 231 in the respective pin opening 212 therein. Each respective pin opening 212 of the plurality of pin openings 212 includes a first tapered section 251 that interfaces with an upper tapered section of the lift pin 231, a first vertical section 252, a second tapered surface 253, a second vertical section 254, and a third tapered section 255 that interfaces with a lower tapered section of the respective lift pin 231. The lift pins 231 are formed of a ceramic material, such as aluminum oxide (Al₂O₃).

The support body 204 includes a plurality of elevated surfaces 240 (three are shown in FIG. 2A) disposed between the recessed surface 245 and the plurality of support surfaces 215. Each elevated surface 240 is disposed about a respective pin opening 212 of the plurality of pin openings 212. The first vertical section 251 of each pin opening 212 includes an inner surface 256, and the first tapered section 252 includes a tapered surface 257 that transitions the inner surface 256 to the respective elevated surface 240. The support surfaces 215 of each of the plurality of support protrusions 210 includes a surface roughness (average surface roughness or Ra) of about 40 micro inches. Each elevated surface 240 intersects one or more sidewalls 258 (one is shown in FIGS. 2A and 2B) of a respective cylindrical band 260 that surrounds the respective 240 elevated surface. The present disclosure contemplates that the cylindrical bands 260 can extend upward to be coplanar with the support surfaces 215 of the support protrusions 210 such that the cylindrical bands 260 contact and support the substrate 107. The present disclosure also contemplates that the cylindrical bands 260 can be shorter than the support protrusions 210 such that the cylindrical bands 260 are at a gap from the substrate 107. In one embodiment, which can be combined with other embodiments, each of the elevated surfaces 240 has an outer diameter OD1 that is 0.2 inches or greater, and each of the cylindrical bands 260 has an outer diameter OD2 that is 0.3 inches or greater. Each pin opening 212 includes an upper vertical section 271 having a vertical inner surface 272 that transitions the respective elevated surface 240 to the respective tapered surface 257. The tapered surface 257 is disposed below the elevated surface 240. A corner that transitions the tapered surface 257 to the vertical inner surface 272 is spaced from the elevated surface 240 by the second height H2 described below.

A circular gap 261 can be disposed about each cylindrical gap 260 and between the respective cylindrical gap 260 and adjacent support protrusions 210. As shown in FIG. 2A, each cylindrical gap 260 can remove a section of the rectangular shape of adjacent support protrusions 210 such that the support protrusions 210 can include arcuate sides that face the respective support protrusion 210.

The plurality of support surfaces 215 are disposed at a first height H1 relative to the recessed surface 245, and the plurality of elevated surfaces 240 are disposed at a second height H2 relative to the recessed surface 245. The second height H2 is less than the first height H1. The recessed surface 245 can be referred to as a base surface of the support body 204. The second height H2 is a fraction F1 of the first height H1. In one embodiment, which can be combined with other embodiments, the fraction F1 is within a range of 0.3 to 0.8. Each of the first height H1 and the second height H2 is within a range of 5 microns to 75 microns. In one embodiment, which can be combined with other embodiments, the first height H1 is within a range of 25 microns to 35 microns, and the second height H2 is within a range of 7 microns to 24 microns. In one embodiment, which can be combined with other embodiments, the second height H2 is within a range of 25 microns to 35 microns, and the first height H1 is within a range of 40 microns to 50 microns. In one embodiment, which can be combined with other embodiments, a difference between the first height H1 and the second height H2 is within a range of 10 microns to 20 microns. In one embodiment, which can be combined with other embodiments, the recessed surface 245 of an Ra that is greater than an Ra of the support surfaces 215 of each of the support protrusions 210. In one example, which can be combined with other examples, the Ra of the recessed surface 245 is about 63 micro inches.

The substrate support 204 can be a part of the pedestal 104, such as a top plate that is mounted to a base plate of the pedestal 104. The base plate is coupled to the shaft 143.

The substrate 107 is positioned on and supported on the outer support surface 202 and the plurality of support surfaces 215 for a substrate processing operation. Cavities 263 are disposed between the elevated surfaces 240 and a backside surface of the substrate 107. A plenum 264 is disposed between the recessed surface 245 and the backside surface of the substrate 107. The cavities 263 have a cavity depth (between the respective elevated surface 240 and the substrate 107) and the cavity depth is less than a plenum depth (between the recessed surface 245 and the substrate 107) of the plenum 264. During the substrate processing operation, the substrate 107 is heated using the support body 204, and the heat is conducted to the substrate 107 through the support protrusions 210. The heat is also radiated and conducted through the plenum 264 from the recessed surface 245. The support body 204 includes one or more vacuum openings 267 (one is shown in FIG. 2A) formed in the recessed surface 245. Gases (such as air and/or process gases) are removed from the plenum 264 through the one or more vacuum openings 267 to generate a pressure differential that facilitates chucking the substrate 107 to the support body 204. The pressure differential and/or the chucking voltage can be used to chuck the substrate 107 to the outer support surface 202 and the support surfaces 215.

Additionally, the heat is radiated and conducted through the cavities 263 from the elevated surfaces 240, from the tapered surfaces 257, and from the lift pins 231. The heat transferred through the cavities 263 is increased by having elevated surfaces 240 at the second height H2 that is less than the first height H1. The cavities 263 have a cavity depth that is equal to the first depth D1 described below. The plenum 254 has a plenum depth that is equal to the second depth D2 described below. Using the cavity depth of the cavities 263 that is shorter than the plenum depth of the plenum 264 facilitates increasing heat transfer through the cavities 263 relative to the plenum 264. Increasing the heat transferred through the cavities 263 relative to the plenum 264 facilitates increasing a temperature of zones of the substrate 107 that are vertically aligned with the cavities 263.

Increasing the temperature of the zones vertically aligned above the cavities 263 facilitates more uniform temperatures as compared to zones of substrate 107 that are aligned outside of the cavities 263. Otherwise, the temperature of the zones aligned above cavities 263 can be a difference DIFF of 10 degrees Celsius (or more) lower than the zones aligned outside of the cavities 263. The difference DIFF can be 1% or more of the temperature of the zones aligned outside of the cavities 263. Using the elevated surfaces 240 and the cavities 263, the difference DIFF is less than 1%, such as less than 0.5%. Accordingly, the second height H2 of the elevated surfaces 240 facilitates maintaining temperature uniformity during heating of the substrate 107 even when heat is lost through the lift pins 231 and the pin openings 212. The lost heat would otherwise cause zones of the substrate 107 above the cavities 263 to be heater to a temperature that is less than other zones of the substrate 107, causing non-uniform deposition thereon during a deposition process, such as a CVD process or a PECVD process. The second height H2 of the elevated surfaces 240 facilitates uniform film deposition.

Referring to FIG. 1, the pedestal 104 (which can include the support body 204) can be raised to lower the substrate 107 onto the pedestal 104. The substrate 107 is transferred from a robot and onto the lift pins 231 while the pedestal 104 is in a lowered positioned and the lift pins 231 rest on a base of the chamber body 102. The pedestal 104 is raised relative to lift pins 231 until the pedestal 104 contacts the substrate 107, and the lift pins 231 are lifted from the base of the chamber body 102, suspending the lift pins 231 from the pedestal 104 and supporting the substrate 107 on the pedestal 104. A substrate processing operation is then conducted on the substrate 107. Following the substrate processing operation, the substrate 107 is raised by lowering the pedestal 104. The pedestal 104 is lowered until the lift pins 231 contact the base of the chamber body 102. The pedestal 104, continues to lower such that the lift pins 231 raise relative to the pedestal 104 to contact and then raise the substrate 107 relative to the pedestal 104. The robot then is used to remove the substrate 107 from the lift pins 231 and remove the substrate 107 from the processing chamber 100.

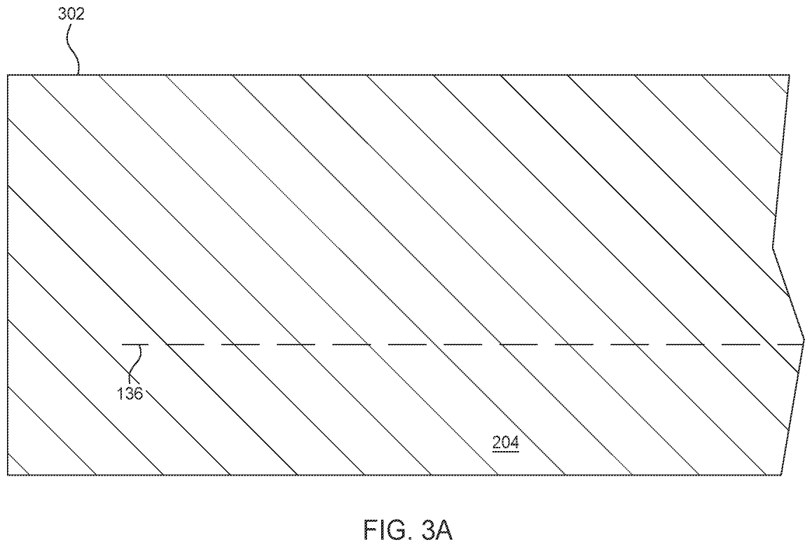

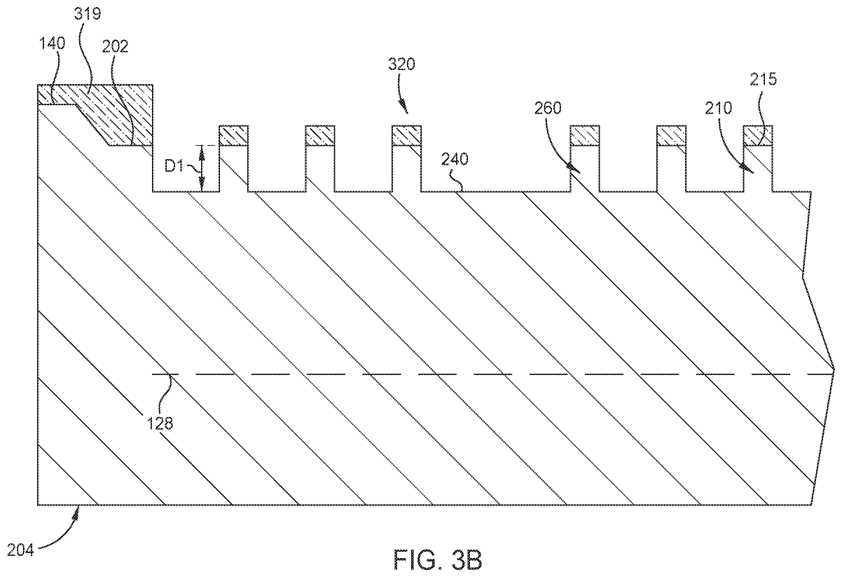

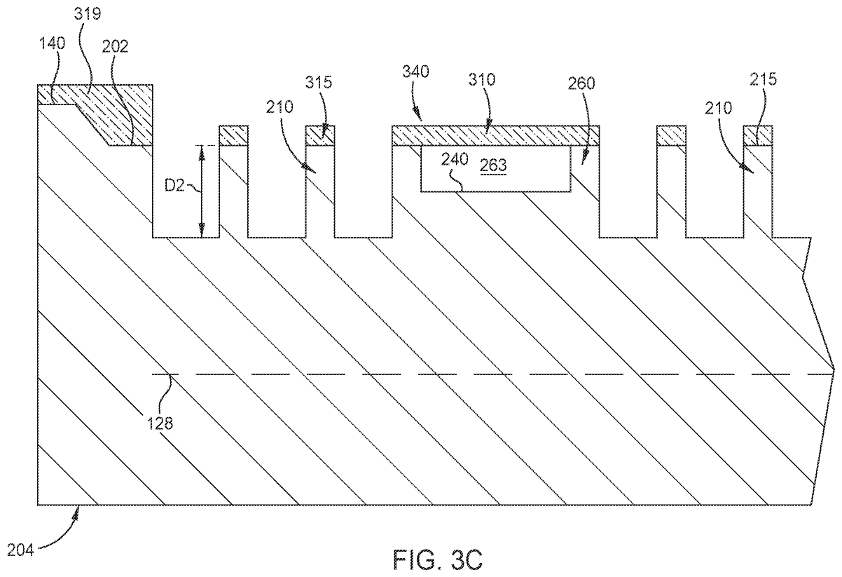

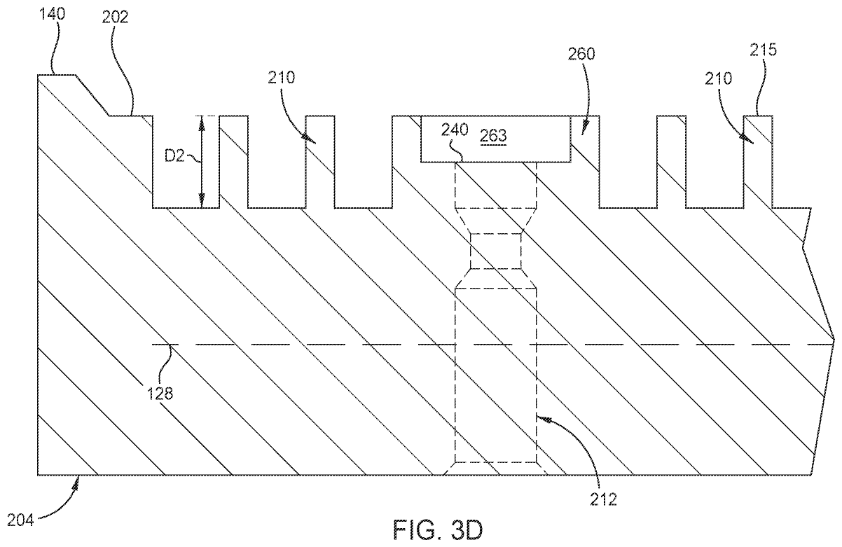

FIGS. 3A-3D are various sectional views showing a method of making the substrate support apparatus 201 shown in FIGS. 2A and 2B, according to one implementation.

FIG. 3A shows the support body 204 having the one or more heaters 128 embedded therein. The present disclosure contemplates that the electrode 136 can also be embedded in the support body 204.

Using a first mask pattern 320 placed on the support body 204 In FIG. 3B, a plurality of support protrusions 210 and the cylindrical bands 260 are formed in the support body 204 by removing a portion of a surface 302 of the support body 204 using a first bead blasting operation. The surface 302 becomes the upper surfaces 215 of the plurality of support protrusions 210, the upper surfaces of the cylindrical bands 260, and the step 140. The present disclosure contemplates that a machining process, such as a milling process, can be conducted on the support body 204 in place of the first bead blasting process.

The first bead blasting operation is conducted to a first depth D1 that is equal to the second height H2 subtracted from the first height H1. The first bead blasting operation removes material to form the elevated surfaces 240.

As shown in FIG. 3C, a second mask pattern 340 is placed over a portion of the support body 204, the cylindrical bands 260, and the support protrusions 210. The second mask pattern 340 also covers the cavities 263. For example, the mask pattern 340 can include a first mask 310, a second mask 315, and a third mask 319. The first mask 310 covers the cylindrical bands 260 and the cavities 263. The second mask 315 covers the support protrusions 210. The third mask 319 covers the step 140 and the outer support surface 202. With the second mask pattern 340 in place a second bead blasting operation is conducted to a second depth D2 that is equal to the first height H1 to form the recessed surface 245 and the support protrusions 210 at the first height H1. The first mask 310 shields the cylindrical bands 260 and the cavities 263 during the second bead blasting operation. The first depth D1 and the second depth D2 are each relative to the outer support surface 202 and the support surfaces 215.

The present disclosure contemplates that other mechanical polishing operations such as wet abrasive blasting and micro-blasting can be used in place of the first bead blasting operation and the second bead blasting operation.

As shown in FIG. 3D, the second mask pattern 340 is removed and the support body 204 is formed to have the support protrusions 210 and the elevated surfaces 240, as shown in FIG. 2B.

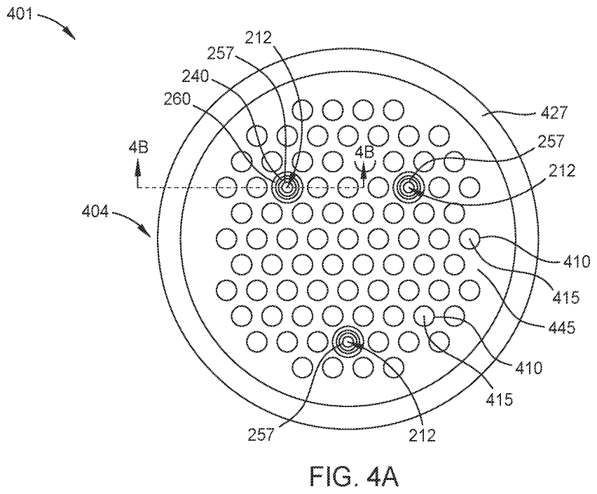

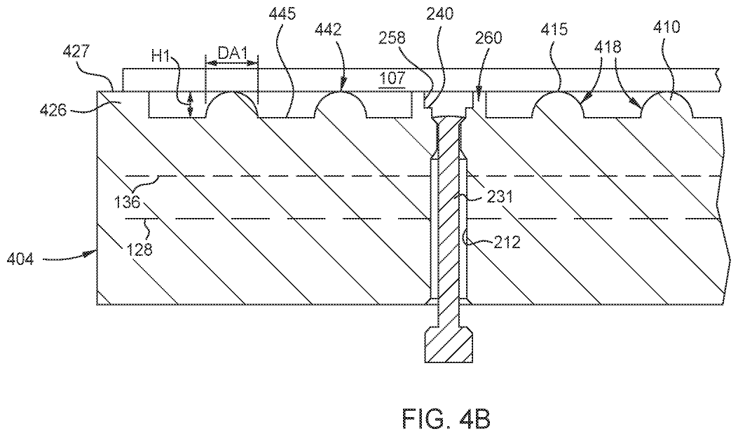

FIG. 4A is a top schematic plan view of a substrate support apparatus 401, according to one implementation. FIG. 4B is a schematic cross-sectional view of the substrate support apparatus 401 shown in FIG. 4A, according to one implementation. The substrate support apparatus 401 can be used for the pedestal 104 shown in FIG. 1.

The substrate support apparatus 401 includes a support body 404. The support body 404 includes a substrate support face 442. The substrate support face 442 includes a base surface 445, and a plurality of support protrusions 410 extending from the base surface 445. The plurality of support protrusions 410 have a plurality of support surfaces 415. The support body 404 also includes a ledge 426. In one embodiment, which can be combined with other embodiments, the ledge 426 includes an outer support surface 427 disposed outwardly of and peripherally around the base surface 445 and the support protrusions 410. In one embodiment, which can be combined with other embodiments, the base surface 445 is a recessed surface that is recessed relative to the outer support surface 427 and the support protrusions 410. The support body includes the plurality of pin openings 212 configured to received the lift pins 231 therein. The plurality of elevated surfaces 240 are disposed between the base surface 445 and the plurality of support surfaces 415. The substrate 107 is supported on the outer support surface 427 and the support surfaces 415 during the substrate processing operation.

As shown in FIGS. 4A and 4B, the support protrusions 410 are arcuate in shape, such as circular in shape. As shown in FIG. 4B, the support protrusions 410 are raised dimples, such as hemispherical protrusions, that are arcuate in shape and each having an arcuate surface 418. Each of the support surfaces 415 is an end of a respective arcuate surface 418. The present disclosure contemplates that the support protrusions 410 can be cylindrical in shape.

The support protrusions 410 can be disposed along the base surface 445 in a uniform arrangement or a non-uniform arrangement. The support protrusions 410 may be disposed along the base surface 445 in any suitable arrangement, for example, concentric circles or hexagonal arrangements. The number (e.g. density) and dimensions of the support protrusions 410 may be selected to improve electrostatic chucking of substrates. In one embodiment, which can be combined with other embodiments, the support protrusions 410 have a surface roughness within a range of 1 Ra to 64 Ra.

The support protrusions 410 each have a diameter DA1 within a range of 0.25 mm to 2.5 mm. The support surfaces 415 of the support protrusions 410 are formed at the first height H1 relative to the base surface 445. The first height H1 is the same as a height of the outer support surface 327 of the ledge 416. The present disclosure contemplates that the first height H1 of the support protrusions 410 can be greater or less than the height of the outer support surface 327 of the ledge 226. The second height H2 of the elevated surfaces 240 is relative to the base surface 445. A distance between individual support protrusions 410 is within a range of 0.1 mm to 3 mm. A ratio of the distance between individual support protrusions 410 and a diameter of the base surface 445 is within a range of 0.01 to 0.2, such as within a range of 0.05 to 0.15, for example 0.1.

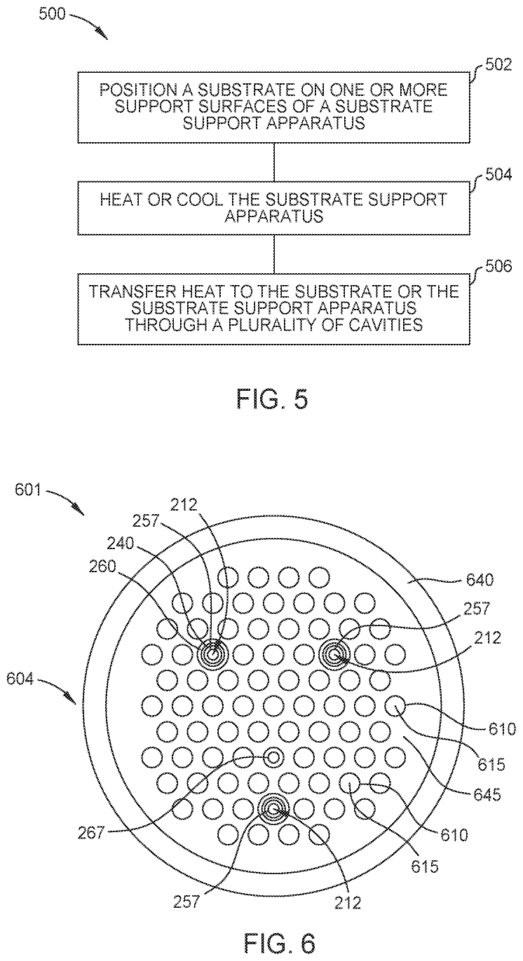

FIG. 5 is a schematic block diagram view of a method 500 of processing substrates, according to one implementation. At operation 502, the method 500 includes positioning a substrate on one or more support surfaces of a substrate support apparatus disposed in a processing chamber. The one or more support surfaces can include a plurality of support surfaces of a plurality of support protrusions and/or an outer support surface disposed outwardly of and peripherally around the support surfaces. The positioning of operation 502 includes moving the substrate support apparatus relative to a plurality of lift pins disposed in a plurality of pin openings of the substrate support apparatus.

The method 500 includes conducting a substrate processing operation on the substrate. The substrate processing operation can include a deposition operation such as a CVD operation or a PECVD operation. The substrate processing operation can include an etching operation, an oxidation operation, an anneal operation, and/or an ion implantation operation.

The substrate processing operation includes, at operation 504, heating the substrate support apparatus. The substrate support apparatus is heated to a temperature within a range of 500 degrees Celsius to 560 degrees Celsius. The present disclosure contemplates that operation 504 may include cooling (e.g., dissipating heat from) the substrate support apparatus in place of or in addition to the heating of the substrate support apparatus.

The substrate processing operation includes, at operation 506, transferring heat to the substrate (from the substrate support apparatus) through a plurality of cavities positioned between the substrate and a plurality of elevated surfaces. The plurality of elevated surfaces are disposed between the one or more support surfaces and one or more recessed surfaces of the substrate support apparatus. The present disclosure also contemplates that operation 506 may include—in place of or in addition to the transferring heat to the substrate—transferring heat to the substrate support apparatus (from the substrate) through the plurality of cavities.

One or more of the operations 502-506 can be repeated. According to one implementation, heating can occur at operation 504, then heat can be transferred to the substrate at operation 506, then cooling can occur at operation 504, and then heat can be transferred to the substrate support apparatus at operation 506.

Each elevated surface of the plurality of elevated surfaces is disposed about a respective pin opening of the plurality of pin openings. In one embodiment, which can be combined with other embodiments, the one or more support surfaces are part of a plurality of support posts extending from the one or more recessed surfaces. The one or more support surfaces are disposed at the first height H1 relative to the one or more recessed surfaces, and the plurality of elevated surfaces are disposed at the second height H2 relative to the one or more recessed surfaces. The second height H2 is less than the first height H1. In one embodiment, which can be combined with other embodiments, the one or more support surfaces are part of a plurality of raised dimples extending from the one or more recessed surfaces. The plurality of elevated surfaces are formed at the first depth D1 relative to the one or more support surfaces. The one or more recessed surfaces are formed at the second depth D2 relative to the one or more support surfaces. The second depth D2 is greater than the first depth D1.

FIG. 6 is a top schematic plan view of a substrate support apparatus 601, according to one implementation. The substrate support apparatus 601 is similar to the substrate support apparatus 401 shown in FIG. 4A, and includes one or more of the aspects, features, components, and/or properties thereof. A support body 604 includes a plurality of recesses 610 formed in a single support surface 645. A step 640 can be disposed peripherally about the single support surface 645. The step 640 can extend (such as angle) above or below the single support surface 645. A substrate 107 can be supported on the single support surface 645. In one embodiment, which can be combined with other embodiments, step 640 is above the single support surface 645, and the substrate 107 rests on the step 640 in addition to or instead of the single support surface 645. The plurality of recesses 610 formed in the single support surface 645 define a plurality of recessed surfaces 615 that are recessed relative to the single support surface 645. The plurality of recesses 610 can be cylindrical and/or can be channels, such as channels formed in an arcuate fashion in a plane parallel to the substrate 107. The plurality of recesses 610 can be dimples that extend into the single support surface 645. The present disclosure contemplates that aspects of the present disclosure, such as the elevated surfaces 240 disposed about the pin openings 212, can be used in substrate support apparatus having. In such an embodiment,

The cylindrical bands 260 can be recessed below the single support surface 645, as shown in FIG. 6. The cylindrical bands 260 can be omitted such that the cavities 263 are recesses formed in the single support surface 645 and such that the elevated surfaces 240 are recessed into the single support surface 645. One or more vacuum openings 267 can be formed in one or more of the plurality of recessed surfaces 615 to remove gases from the plurality of recesses 610 during a substrate processing operation.

Benefits of the present disclosure include at least enhanced and efficient temperature uniformity during substrate processing (such as efficient temperature uniformity during heating and/or cooling of the substrate), uniform film deposition on substrates, reduced likelihood of component breakage, increased throughput, reduced costs, and less complex

It is contemplated that one or more aspects disclosed herein may be combined. As an example, one or more aspects, features, components, and/or properties of the processing chamber 100, the substrate support apparatus 201, the method of making the substrate support apparatus 201 shown in relation to FIGS. 3A-3D, the substrate support apparatus 401, the method 500, and/or the substrate support apparatus 601 may be combined. Moreover, it is contemplated that one or more aspects disclosed herein may include some or all of the aforementioned benefits.

The present disclosure achieves the aforementioned benefits over other operations that involve decreasing the size of lift pins and pin openings, and operations that involve increasing heat generated in areas of the heater that are adjacent the pin openings. For example, reducing the size of lift pins and pin openings involve breakage of the lift pins, resulting in machine downtime and replacement costs. As another example, increasing heat generated in areas of the heater that are adjacent the pin openings still involves temperature non-uniformity in zones of the substrate that are aligned above the lift pins and pin openings. Additionally, increasing the heat fails to account for non-uniformities during cooling of the substrate. Attempts have been made, but failed, to solve the problems of temperature non-uniformity. The present disclosure achieves unexpected results in reducing the temperature non-uniformity of the substrate as it was previously thought that using elevated surfaces 240 would complicate manufacturing.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A substrate support apparatus comprising a support body, the support body comprising:
a substrate support face, the substrate support face comprising:
an outer support surface,
a recessed surface disposed inwardly of the outer support surface, and
a plurality of support protrusions extending from the recessed surface, the plurality of support protrusions having a plurality of support surfaces;
a plurality of pin openings configured to received lift pins therein;
a plurality of elevated surfaces disposed between the recessed surface and the plurality of support surfaces, each elevated surface of the plurality of elevated surfaces being disposed about a respective pin opening of the plurality of pin openings.

2. The substrate support apparatus of claim 1, wherein the support body is part of an electrostatic chuck.

3. The substrate support apparatus of claim 1, wherein the substrate support apparatus further comprises one or more resistive heaters embedded in the pedestal.

4. The substrate support apparatus of claim 1, wherein each respective pin opening of the plurality of pin openings comprises a vertical section having an inner surface and a tapered section having a tapered surface that transitions the inner surface to the elevated surface.

5. The substrate support apparatus of claim 1, wherein the plurality of support surfaces are disposed at a first height relative to the recessed surface, the plurality of elevated surfaces are disposed at a second height relative to the recessed surface, and the second height is less than the first height.

6. The substrate support apparatus of claim 5, wherein each elevated surface of the plurality of elevated surfaces intersects one or more sidewalls of a respective cylindrical band that surrounds the elevated surface.

7. The substrate support apparatus of claim 5, wherein the second height is a fraction of the first height, and the fraction is within a range of 0.3 to 0.8.

8. The substrate support apparatus of claim 5, wherein the first height is within a range of 25 microns to 35 microns, and the second height is within a range of 7 microns to 24 microns.

9. The substrate support apparatus of claim 8, wherein each elevated surface of the plurality of elevated surfaces has an outer diameter that is 0.2 inches or greater.

10. A substrate support apparatus comprising a support body, the support body comprising:
a substrate support face, the substrate support face comprising:
a base surface, and
a plurality of support protrusions extending from the base surface, the plurality of support protrusions having a plurality of support surfaces;
a plurality of pin openings configured to received lift pins therein;
a plurality of elevated surfaces disposed between the base surface and the plurality of support surfaces, each elevated surface of the plurality of elevated surfaces being disposed about a respective pin opening of the plurality of pin openings.

11. The substrate support apparatus of claim 10, wherein the plurality of support protrusions are support posts that are rectangular in shape.

12. The substrate support apparatus of claim 10, wherein the plurality of support protrusions are raised dimples that are arcuate in shape.

13. The substrate support apparatus of claim 10, wherein the plurality of support surfaces are disposed at a first height relative to the recessed surface, the plurality of elevated surfaces are disposed at a second height relative to the recessed surface, and the second height is less than the first height.

14. The substrate support apparatus of claim 13, wherein each elevated surface of the plurality of elevated surfaces intersects one or more sidewalls of a respective cylindrical band that surrounds the elevated surface.

15. The substrate support apparatus of claim 13, wherein the second height is a fraction of the first height, and the fraction is within a range of 0.3 to 0.8.

16. The substrate support apparatus of claim 13, wherein the first height is within a range of 25 microns to 35 microns, and the second height is within a range of 7 microns to 24 microns.

17. The substrate support apparatus of claim 16, wherein each elevated surface of the plurality of elevated surfaces has an outer diameter that is 0.2 inches or greater.

18. A method of processing substrates, comprising:
positioning a substrate on one or more support surfaces of a substrate support apparatus disposed in a processing chamber, the positioning comprising:
moving the substrate support apparatus relative to a plurality of lift pins disposed in a plurality of pin openings of the substrate support apparatus;
conducting a substrate processing operation on the substrate, the substrate processing operation comprising:
heating the substrate support apparatus, and
transferring heat to the substrate through a plurality of cavities positioned between the substrate and a plurality of elevated surfaces disposed between the one or more support surfaces and one or more recessed surfaces of the substrate support apparatus, each elevated surface of the plurality of elevated surfaces being disposed about a respective pin opening of the plurality of pin openings.

19. The method of claim 18, wherein the one or more support surfaces are part of a plurality of support posts extending from the one or more recessed surfaces, the one or more support surfaces are disposed at a first height relative to the one or more recessed surfaces, the plurality of elevated surfaces are disposed at a second height relative to the one or more recessed surfaces, and the second height is less than the first height.

20. The method of claim 18, wherein the one or more support surfaces are part of a plurality of raised dimples extending from the one or more recessed surfaces, the plurality of elevated surfaces are formed at a first depth relative to the one or more support surfaces, the one or more recessed surfaces are formed at a second depth relative to the one or more support surfaces, and the second depth is greater than the first depth.
